(19) United States
(12) Patent Application Publication
(10) Pub. No.: US 2020/0049909 A1
(43) Pub. Date: Feb. 13, 2020

(54) SILICON PHOTONIC SOLDER REFLOWABLE ASSEMBLY

(71) Applicant: Hewlett Packard Enterprise Development LP, Houston, TX (US)

(72) Inventors: Sagi Mathai, Sunnyvale, CA (US); Michael Rene Ty Tan, Menlo Park, CA (US); Marco Fiorentino, Mountain View, CA (US); Paul Kessler Rosenberg, Sunnyvale, CA (US); David Kielpinski, Palo Alto, CA (US); Wayne Victor Sorin, Palo Alto, CA (US)

(21) Appl. No.: 16/526,374

(22) PCT Filed: Jan. 30, 2017
(86) PCT No.: PCT/US2017/015632

§ 371 Date: Jul. 30, 2019

(51) Int. Cl. G02B 6/42; G02B 6/34; H01L 23/544

(52) U.S. Cl. CPC G02B 6/4238; G02B 6/34; H01L 24/81; G02B 6/4232; H01L 23/544; G02B 6/4206

(57) ABSTRACT

In some examples a silicon photonic (SiPh) solder reflowable assembly may comprise a silicon interposer bonded to an organic substrate, the silicon interposer having an optical grating disposed on the interposer to couple an optical signal, a lens array chip, the lens array comprising one or more lenses on a wafer, the lens array chip flip chip reflowed to the silicon interposer by a bonding agent and the one or more lenses having a predetermined shape that expands, collimates, and tilts a beam of the optical signal exiting the grating. The wafer has a coefficient of thermal expansion (CTE) that matches silicon and the one or more lenses and the grating are aligned in such a way the optical signal enters the grating at a desired angle.

### BACKGROUND

Silicon photonics (SiPh) is the study and application of photonic systems which use silicon as an optical medium. The silicon is usually patterned with precision into microphotonic components in such a way as to achieve a desired functionality. An interposer serves as a substrate on which multiple components and devices are interconnected and interfaced with external substrates. Flip chip solder reflow is a technique for bonding semiconductor devices, integrated circuits, electrical packages, etc. to external circuitry.

### BRIEF DESCRIPTION OF THE DRAWINGS

FIG. 1 illustrates an example silicon photonic (SiPh) solder reflowable assembly.

FIG. 2 illustrates another example SiPh solder flowable assembly.

FIG. 3 illustrates an example SiPh solder reflowable assembly with associated components.

FIG. 4 illustrates another example SiPh solder reflowable assembly with associates components.

FIG. 5 illustrates an example of a flux diagram for fabricating a silicon photonic (SiPh) solder reflowable assembly.

### DETAILED DESCRIPTION

This disclosure relates to a silicon photonic (SiPh) solder reflowable assembly with expanded beam lens arrays and expanded beam single mode fiber connectors and methods to make the same. Single mode fibers (SMF) can be pigtailed (i.e. permanently attached) to SiPh devices where the assembly may include a detachable electrical connector to energize the SiPh device in order to actively align the SMF. Active alignment refers to energizing the SiPh device electrically and/or optically while the SMF is aligned to the SiPh until the desired optical and/or electrical signal is maximized. In the present solution the SiPh assembly avoids active alignment, leverages wafer scale manufacturing and testing techniques, enables detachable optical connections, and can be solder reflowed to external circuitry.

Microlenses can be fabricated on a glass, glass ceramic, or Si wafer that can be reflowed to the SiPh interposer at the wafer scale. Glass lenses can be more robust and easier to clean compared to plastic lenses. A wafer is a thin slice of material, such as single crystal silicon and glass. The proposed assembly takes advantages of wafer scale packaging, testing and flip chip solder reflow.

A large number of separate dies can be fabricated on a single wafer. The dies can be separated by dicing lanes on the wafer, and after fabrication of the microlenses, SiPh devices, or integrated circuits, the wafer can be sawed along the dicing lanes to form the individual dies. After the cites are separated, individual testing of the dies may take place. Alternatively, the individual dies on the wafer may be tested before sawing the wafer along the dicing lanes.

Wafer scale electrical/optical testers with a lower cost and higher throughput can be used as the assembly is provisioned with expanded beam lens arrays suitable for expanded beam single mode fiber connectors. Flip chip solder reflow ensures precise self-alignment between bonded elements within the assembly. In the present solution, solder self-alignment of a lens chip to the SiPh interposer and vision alignment of an optical socket to the lens chip can enable passive alignment of detachable expanded beam single mode optical connectors to the SiPh interposer and thus avoiding energizing the SiPh devices during assembly.

Optical signals entering or exiting the SiPh interposer can be coupled to optical waveguides on the SiPh interposer using one or more grating couplers (e.g. a grating coupler array). Optical signals entering or exiting the grating couplers can be coupled to fiber optic connectors using a lens chip. The lenses optical axes are offset with respect to the grating coupler to tilt the optical signals exiting and entering the lenses. The lenses serve to collimate and tilt, and focus and tilt the optical signals exiting and entering the grating couplers, respectively, and couples the signals to expanded beam fiber optic connectors. By leveraging the precision manufacturing and alignment capabilities available in foundries, such as but not limited to silicon, microelectromechanical system (MEMS), and micro-optics foundries, a SiPh interposer assembly can be fabricated to couple optical signals from associated devices to a fiber optic connector with high precision and favorable alignment tolerances.

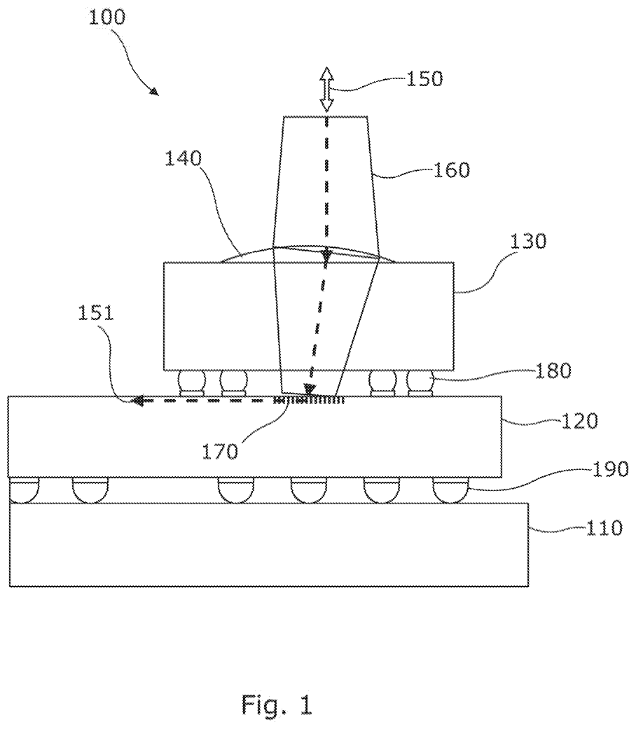

FIG. 1 illustrates an example SiPh solder reflowable assembly 100 according to an example of the present disclosure that comprises an organic substrate 110 bonded by a bonding agent 190 (e.g. solder) to a SiPh interposer 120, the SiPh interposer 120 having an optical grating 170 disposed on the SiPh interposer 120 to couple an optical signal 150. Passive and active optical elements, such as but not limited to waveguides, modulators, and photodetectors, can be fabricated on the SiPh interposer to route, modulate, and detect optical signals, respectively.

The assembly 100 comprises a lens array chip 130 (e.g. a glass lens chip) comprising one or more glass microlenses 140 on a wafer on an array distribution. The lens array chip 130 can he reflowed to the SiPh interposer 120 by a bonding agent 180 (e.g. solder) at the wafer scale and the array of microlenses 140 may have a predetermined shape that expands and collimates a beam of the optical signal 151 exiting the optical grating 170. The wafer of the lens array chip 130 can be fabricated from a substantially transparent glass material with a Coefficient of Thermal Expansion (CTE) that matches silicon in order to facilitate precision alignment of the microlenses 140 on the chip 130 to the optical grating 170 on the SiPh interposer 120 when, for example, heat is used in the bonding process. In another examples, the wafer of the lens array chip 130 can comprise silicon to ensure perfect CTE matching between the SiPh interposer and silicon microlens chip. The wafer can comprise an antireflective coating on the backside of the silicon wafer facing the SiPh interposer. The array of microlenses 140 and the optical grating 170 can be aligned in such a way the optical signal enters the grating at a desired angle. The one or more lenses can be made of silicon or glass. Thee microlenses may serve to collimate and focus the optical signals exiting and entering the grating couplers and couples the signals to expanded beam fiber optical connectors to increase the x-y-z alignment tolerances between the microlens array and the fiber optic connector. The microlenses can be formed on the wafer such that, when flip chip solder reflowed to the SiPh interposer, the optical signals traversing through the microlenses can be transmitted and/or received by the gratings at an angle predetermined to optimize signal capture.

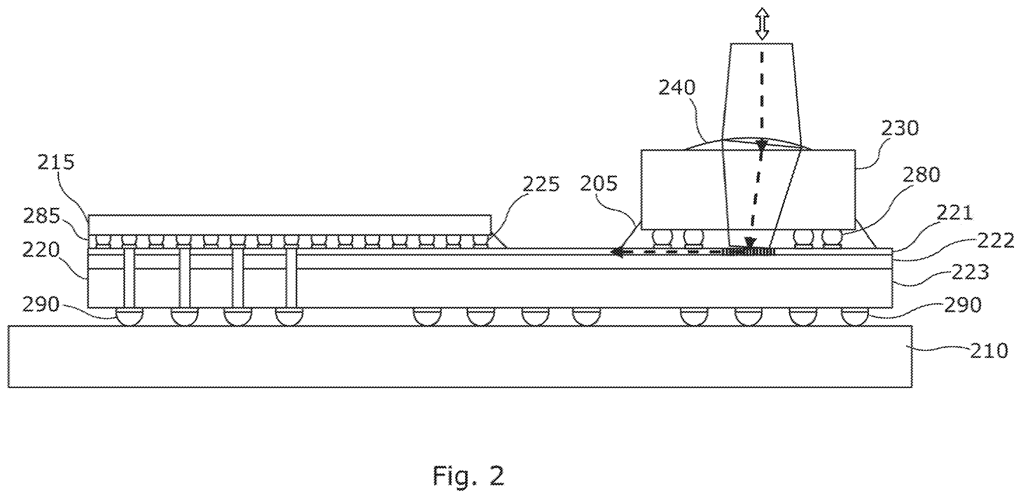

FIG. 2 illustrates an example SiPh solder reflowable assembly 200 according to an example of the present disclosure that includes an optically transparent underfill 205 with a refractive index matched to the wafer of the lens array chip 230 within a range 1.3-2.6. The optically transparent underfill index matched to the glass substrate or wafer of the lens array chip 230 can eliminate optical reflections at the glass substrate-air interface. The optical grating 170 may or may not be overcoated with an optically transparent material such as but not limited to silicon dioxide, silicon oxynitride, or silicon nitride. In some embodiments the overcoated material is index matched to the optical underfill 205 to prevent unwanted reflections at the overcoated material interface within a range 1.3-2.6. The lenses 240 can comprise an antireflective coating to prevent signal loss.

Furthermore, assembly 200 comprises n application-specific integrated circuit (ASIC) 215. ASIC's can be a type of Integrated Circuit (IC) chip that have been customized for a particular purpose, reducing the complexity and cost relative to a general-purpose chip. ASIC can be solder reflowed 225 and underfilled 285 to the SiPh interposer 220. The SiPh interposer 220 can comprise an active silicon layer 221 to interface with a surface of the lens array chip 230 shown in FIG. 2. The SiPh interposer 220 can be a layered substrate, with the active silicon layer 221 separated from a layer of silicon 223 by an insulating layer 222 to result in a silicon on insulator (SOI) substrate.

The lens array chip 230 can be reflowed at the wafer scale by a bonding agent 280 to the SiPh interposer 220 as shown in FIG. 2. The bonding agent 280 can be but not limited to solder bump or copper pillar with solder cap. In another example, the bonding agent 280 can comprise mechanical alignment features, polymer, or it could be an optically transparent adhesive. A solder reflowable technique can be used to bond components to provide a SiPh interposer assembly as proposed to interface with detachable alignment tolerant optical connectors. Flip chip solder reflow is a process in which a solder is used to attach components to contacts on a wafer, substrate, or circuit board, after which the entire assembly is subjected to a heat source. Applying heat serves to melt the solder to self-align the components and upon cooling to permanently bond the components. Bonding components by wafer scale solder reflow is less costly and higher throughput compared to soldering components individually. The reflow process can be implemented at temperatures that melt the solder and heat the adjoining surfaces without overheating and damaging the associated components. The SiPh interposer 220 reflowed by bonding agent 290 to the organic substrate 210 can also comprise the use of solder. The SiPh interposer assembly can be flip chip solder reflowed to a larger PCB.

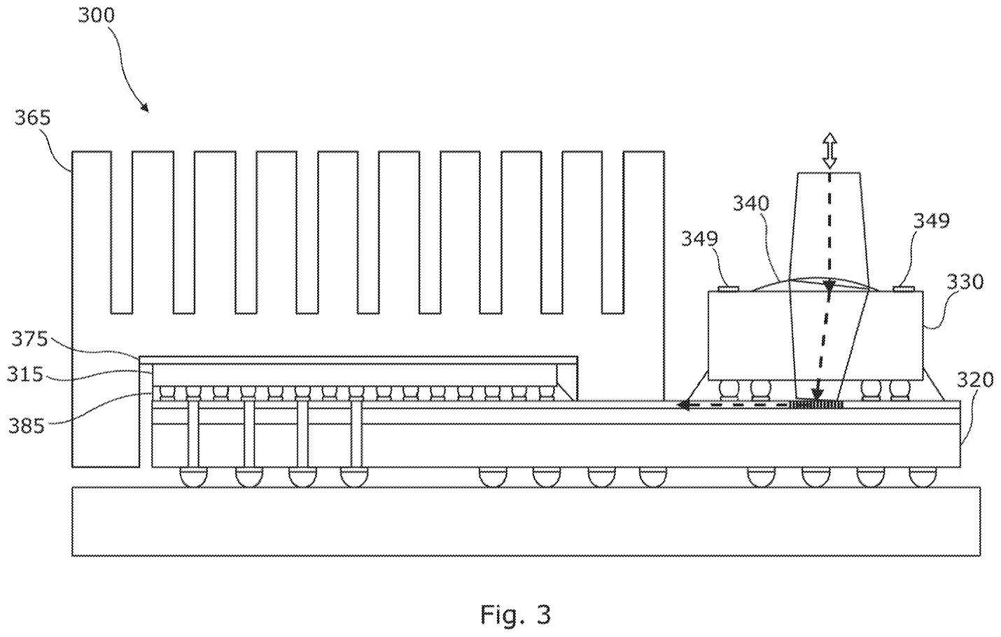

Turning now to FIG. 3, this figure illustrates an example SiPh solder reflowable assembly comprising a heat sink 365 that can be attached separately, to the IC 315 with a thermal interface material 375, the lens array chip 330, or the SiPh interposer, or a combination of the aforementioned objects. The IC 315 may be underfilled 385. The heat sink 365 can be in thermal communication with at least one of the silicon interposer 320, the IC 315 and the lens array chip 330. The bonding process can include, but not limited to, fusion, anodic, adhesive, metal bonding, or the like. Furthermore, a plurality of vision alignment fiducials 349 etched into or deposited onto (e.g. metal) the chip 330 ensure precise x-y-z and angular alignment between an optical socket and the lens array chip 330. The plurality of vision alignment fiducials 349 can be etched, deposited, or patterned on the wafer of the lens array chip 330 e.g. on the same surface as the microlenses.

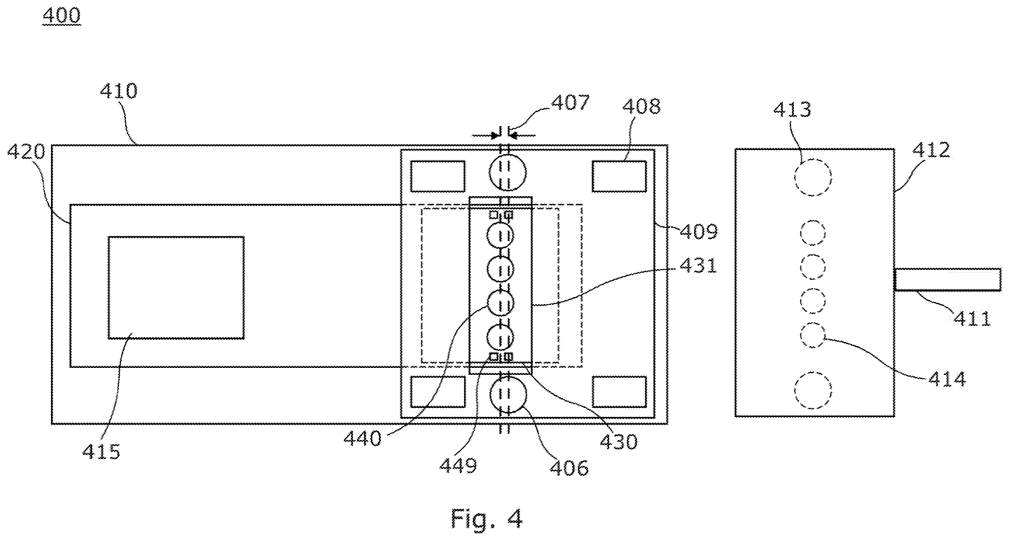

As shown in FIG. 4, an example SiPh solder reflowable assembly comprises a lens array of four microlenses 440 that is provided on an exposed surface of the lens array chip 431 as well as four vision alignment fiducials 449. Each of the microlenses 440 can be aligned with respect to an optical grating formed on the SiPh substrate 420. Furthermore, FIG. 4 shows an optical socket 409 established on the organic substrate 410 having an offset with respect to the lens array chip 430 based on the four vision alignment fiducials 449. Hence, the microlenses optical axes are offset to the optical grating. The four vision alignment fiducials 449 can provide a reference position that indicates where the optical socket should be established on the organic substrate 410 to achieve efficient coupling between an optical connector and the SiPh interposer assembly. The optical socket 409 further comprises a large through hole 430 that permits a line of sight between the microlenses 440 on the lens array chip 431 and an optical connector 412 once the optical socket 409 is established upon the organic substrate 410. In some examples, the through hole 430 may be covered and sealed with a material (such as glass, plastic, or silicon) that is transparent to the optical signals. In other examples, the optical socket 409 may be injection molded using a material that can survive solder reflow processes and is transparent or semitransparent to the optical signals.

The offset performed between the socket and the lens array chip permits to create an offset between the optical axis of the light exiting the fiber (i.e. the light signal inputting the lens array chip 430) and the microlenses 440 optical axes. Hence, the offset can naturally tilt the light exiting the lenses and falling onto the SiPh interposer 420. The light must be tilted in order to efficiently couple the signal entering the optical grating coupled to an optical waveguide (not shown in FIG. 4) on the silicon photonic interposer 420.

Moreover, each microlens 440 can be aligned with an optical fiber by mating the optical fiber connector 412 with the optical socket 409. In the example shown in FIG. 4, the optical connector 412 comprises four lenses 414 coupled to four optical fibers 411. Each fiber 411 of the optical connector corresponds to a respective lens 414 of the optical connector 412, and consequently corresponds to a respective microlens 440 of the lens array chip 430. The optical connector 412 can mate to the optical socket 409 in such a way that the optical fiber connector 412 may not be in contact with the SiPh interposer 420 or the lens array chip 430. The optical connector 420 can be e.g. an off the shelf optical connector or a custom optical connector.

The mating performed between the optical socket 409 and the optical fiber connector 412, as described herein can be performed based e.g. on complementary mechanical alignment features. In particular, the optical socket 409 comprises two offset optical connector guide holes 406. The holes 406 in the optical socket 409 can mate with pins 413 established on the optical fiber connector 412 that can be complementary to the holes 406 and may permit mechanical alignment. Alternatively, the complementary mechanical alignment features on the socket 489 may be a hole and a pin, in which case, the hole and pin would mate with a pin and hole on the optical connector 412, respectively.

Flat coplanar surfaces over the area of the optical socket 409 and the optical connector 412 may be challenging. In this respect, the optical socket 409 and the optical connector 412 can be implemented with flat parallel complementary surfaces 408 for physical contact between the optical socket 409 and the optical connector 412. The flat parallel complementary surfaces 408 may permit flat coplanar surface over the area of the plastic optical socket 409 and the optical fiber connector 412. Hence, it may not be required to mate the whole surface of the optical socket 409 with the optical connector in order to be coplanar to it.

Hence based on the mechanical alignment features 406 and the flat parallel complementary surfaces 408, the alignment between the optical socket 409 and the optical fiber connector can be assured in all six axes and the one or more optical fibers inside the optical connector can be aligned to the microlenses 440 on the lens array chip 430 on the SiPh interposer 410.

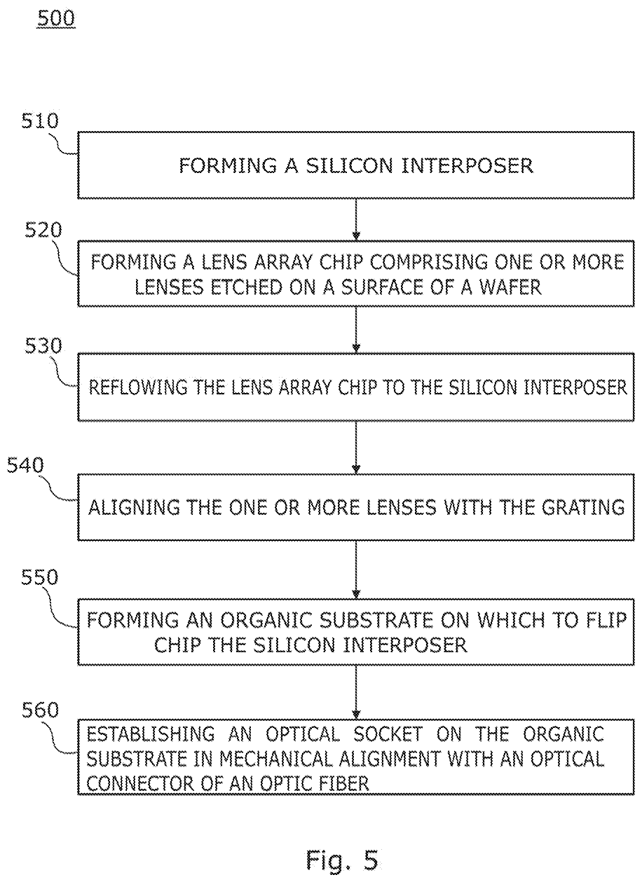

FIG. 5 shows an example of a flux gram 500 for fabricating a silicon photonic (SiPh) solder reflowable assembly:

The diagram 500 comprises step 510 for forming a silicon interposer. The silicon interposer can comprise an insulator on a given surface of a silicon substrate, a silicon active layer on another surface of the insulator that is opposite to the silicon substrate and an optical grating on a given surface of the silicon active layer that is opposite to the insulator. The optical grating can comprise a grating coupler array.

The diagram 500 comprises step 520 for forming a lens array chip, the lens array chip comprising one or more microlenses etched on a surface of a wafer. The wafer can comprise silicon or another material. The one or more microlenses can be made of glass or silicon. The one or more microlenses can be precisely aligned to the optical grating and adapted to expand, collimate, and tilt on optical signal beam exiting the grating in order to increase the alignment tolerance in the x-y-z plane. The wafer is CTE matched to the silicon interposer to maintain alignment over temperature. The microlenses of the wafer serve to collimate and focus the optical signals exiting and entering the grating coupler array and couples the signals to expanded beam fiber optic connectors.

The diagram 500 comprises step 530 for reflowing the lens array chip to the silicon interposer at the wafer scale by a bonding agent. A bonding agent can be used to bond the lens array chip to the SiPh interposer. The bonding agent can be e.g. solder. In another examples, the bonding agent can comprise mechanical alignment features, optically transparent adhesive, polymer, epoxy, underfill, glass frit, or metal. In some examples, the bonding agent creates a bond line over the entire surface area of the lens array chip facing the SiPh interposer. In other examples, the bonding agent is restricted to the perimeter region of the lens array chip or over a subset of the surface area of the lens chip facing the SiPh interposer. The wafer of the lens array chip can be a glass with a CTE matched to the SiPh interposer that facilitates precision bonding when, for example, heat is used in the bonding process. In other examples the wafer can comprise silicon to ensure perfect CTE matching between the interposer and silicon microlenses. In some examples, the bonding of the lens array chip to the SiPh interposer can comprise flip chip solder reflowing the lens array chip to the SiPh interposer at the wafer scale. In some examples the bonding of the lens array chip to the SiPh interposer can be performed with mechanical alignment features from a material comprising one of a polymer, an electroplated metal, glass and silicon.

The diagram 500 comprises step 540 for aligning the one or more lenses with the grating to direct the optical signal entering the grating at a desired angle. The one or more microlenses can be formed on the wafer such that, when bonded to the silicon interposer, the optical signals traversing through the microlenses can be transmitted and/or received by the gratings at an angle predetermined to optimize signal capture. The alignment of the one or more lenses with the grating can comprise an offset to the one or more lenses optical axis with respect to the grating.

The diagram 500 comprises step 550 for forming an organic substrate on which to flip chip the SiPh interposer. Flip chip applies solder bumps that have been deposited onto chip pads. The solder bumps are deposited on the chip pads on the top side of the organic substrate during the final processing step. In order to bound the SiPh interposer to the organic substrate, the SiPh interposer is aligned so that its solder pads align with matching pads on the organic substrate, and then the solder is reflowed to complete the interconnect as shown in FIGS. 1 to 3.

The diagram 508 further comprises step 560 for establishing a plastic optical socket, that can survive multiple solder ref lows, on the organic substrate in mechanical alignment with an optical connector of an optic fiber transmitting the optical signal. Vision alignment fiducials can ensure precise x-y-z and angular alignment between the optical socket and the lens array chip. Vision alignment fiducials can be etched on the wafer of the lens array chip e.g. on the front (microlens side) or back (solder bumped side) of the wafer. The plastic optical socket and the optical connector can be implemented with flat parallel complementary surfaces, wherein the flat parallel complementary surfaces permit alignment between the plastic optical socket and the optical fiber connector. Furthermore, the plastic optical socket and the optical connector can comprise mechanical alignment features. In one example, the plastic optical socket can comprise at least e.g. one or more holes and the optical connector can comprise e.g. one or more complementary pins. The optical socket established on the organic substrate in step 560 may have an offset with respect to the lens array chip formed in step 520 based on the vision alignment fiducials. Hence, the microlenses optical axes can be offset to the optical connector. The vision alignment fiducials can provide a reference position that indicates where the optical socket should be established on the organic substrate 410 to achieve the offset. In another examples, the plastic optical socket may be directly attached to the SiPh interposer in order to improve planarity between the plastic optical socket and the lens array chip.

The offset performed between the socket and the lens chip permits to create an offset between the optical axis of the light exiting the fiber (i.e. the light signal inputting the lens array chip) and the lenses optical axes. Hence, the offset can naturally tilt the light exiting the lenses and falling onto the SiPh interposer. The light must be tilted in order to efficiently couple the signal entering the optical grating coupled to an optical waveguide in the optical SiPh interposer.

In another example step 520 can comprise flip chipping, applying an index matched optically transparent underfill to the lens array chip and testing at the wafer scale in order to eliminate optical reflections. The underfill may also function as a hermetic encapsulant, thus protecting assembly from unwanted harsh chemicals, debris, and the like.

In another example diagram 580 further comprises a step for disposing an integrated circuit (IC) on the SiPh interposer and one or more heat sinks in thermal communication with at least one of the SiPh interposer, IC and the lens array chip, wherein disposing the integrated circuit (IC) further comprises flip chipping, underfilling and testing the IC on the SiPh interposer at the wafer scale.

In another example diagram 500 further comprises a step applying an antireflective coating to the one or more lenses to prevent signal loss. The antireflective coating can also be applied to the lenses where th wafer interfaces with an air gap, thereby reducing optical signal reflection. In another example diagram 500 can comprise applying an antireflective coating on a wafer side facing the interposer (i.e. the non-lensed side of the lens array chip) when the wafer comprises silicon or other relatively high index material.

Furthermore, relative terms used to describe the structural features of the figures illustrated herein are in no way limiting to conceivable implementations. It is, of course, not possible to describe every conceivable combination of components or methods, but one of ordinary skill in the art will recognize that many further combinations and permutations are possible. Accordingly, the invention is intended to embrace all such alterations, modifications, and variations that fall within the scope of this application, including the appended claims. Additionally, where the disclosure or claims recite “a,” “an,” “a first,” or “another” element, or the equivalent thereof, it should be interpreted to include one or more than one such element, neither requiring nor excluding two or more such elements.

1. A silicon photonic (SiPh) solder reflowable assembly comprising:
a silicon interposer, the silicon interposer having an optical grating disposed on the interposer to couple an optical signal;
an organic substrate bonded to the silicon interposer;
a lens array chip, the lens array chip comprising one or more lenses on a wafer, the lens array chip reflowed to the silicon interposer by a bonding agent and the one or more lenses having a predetermined shape that expands, collimates, and tilts a beam of the optical signal exiting the grating;
wherein the wafer has coefficient of thermal expansion (CTE) that matches silicon, and
wherein the one or more lenses and the grating are aligned in such a way that the optical signal enters the grating at a desired angle.

2. The silicon photonic (SiPh) solder reflowable assembly of claim 1 further comprising an index matched optically transparent underfill between the lens array chip and the silicon interposer.

3. The silicon photonic (SiPh) solder reflowable assembly of claim 1 wherein the wafer and the one or more lenses comprise silicon, and
the wafer comprises an antireflective coating on a wafer side facing the interposer.

4. The silicon photonic (SiPh) solder reflowable assembly of claim 1 wherein the one or more lenses comprise glass.

5. The silicon photonic (SiPh) solder reflowable assembly of claim 3 wherein the one or more lenses comprise an antireflective coating.

6. The silicon photonic (SiPh) solder reflowable assembly of claim 4 wherein the one or more lenses comprise an antireflective coating.

7. The silicon photonic (SiPh) solder reflowable assembly of claim 1 further comprising an optical socket comprising a mechanical alignment feature designed to mate a complementary mechanical alignment feature of an optical connector, the optical connector comprising one or more lenses aligned with one or more optical fibers, each lens of the optical connector corresponding to a respective lens of the lens array chip.

8. The silicon photonic (SiPh) solder reflowable assembly of claim 7, wherein the mechanical alignment feature of the plastic optical socket comprises at least a hole and the complementary mechanical alignment feature of the optical connector comprises at least a pin for mechanical alignment.

9. The silicon photonic (SiPh) solder reflowable assembly of claim 7, wherein the optical socket and the optical connector are implemented with flat parallel complementary surfaces, wherein the flat parallel complementary surfaces permit alignment between the plastic optical socket and the optical fiber connector.

10. The silicon photonic (SiPh) solder reflowable assembly of claim 7, wherein the optical socket is vision aligned to the lenses or fiducials on the lens array chip.

11. The silicon photonic (SiPh) solder reflowable assembly of claim 1, wherein the one or more lenses optical axis is offset to the grating.

12. The silicon photonic (SiPh) solder reflowable assembly of claim 1, further comprising an integrated chip (IC) disposed on the silicon interposer and one or more heat sinks in thermal communication with at least one of the silicon interposer, IC and the lens array chip.

13. A method for fabricating a silicon photonic (SiPh) solder reflowable assembly, comprising:
forming a silicon interposer, comprising:
an insulator on a given surface of a substrate;
an active layer on another surface of the insulator that is opposite the substrate; and
a grating on a given surface of he active layer that is opposite to the insulator;
forming a lens array chip, the lens array chip comprising one or more lenses etched on a surface of a wafer,
wherein the one or more lenses are adapted to expand, collimate, and tilt an optical signal beam exiting the grating,
wherein the wafer is CTE matched to the silicon interposer;
reflowing the lens array chip to the silicon interposer by a bonding agent at the wafer scale;
aligning the one or more lenses with the grating to direct the optical signal entering the grating at a desired angle;
forming an organic substrate on which to flip chip the silicon interposer;
establishing an optical socket on the organic substrate in mechanical alignment with an optical connector of an optic fiber transmitting the optical signal.

14. The method of claim 13, wherein forming the lens array chip further comprises flip chip solder reflow, applying an index matched optically transparent underfill to the lens array chip and testing at the wafer scale.

15. The method of claim 13, further comprising disposing an integrated circuit (IC) on the silicon interposer and one or more heat sinks in thermal communication with at least one of the silicon interposer, IC and the lens array chip, wherein disposing the integrated circuit (IC) further comprises flip chip solder reflow, underfilling and testing the IC on the silicon interposer at the wafer scale.

16. The method of claim 1 wherein bonding the lens array chip to the silicon interposer comprises using one or more alignment features from a material comprising one of a polymer, dielectric, metal, glass and silicon.

17. The method of claim 13, further comprising implementing the optical socket and the optical connector with flat parallel complementary surfaces that permit alignment between the optical socket and the optical fiber connector.

18. The method of claim 13, further comprising:
implementing a mechanical alignment feature on the optical socket, the mechanical alignment feature comprising at least a hole; and
implementing a complementary mechanical alignment feature on the optical connector, the complementary mechanical alignment feature comprising at least a pin.

19. The method of claim 13, wherein performing an alignment of the one or more lenses comprises performing an offset to the on or more lenses optical axis with respect to the grating.

20. The method of claim 13, further comprising:
applying an antireflective coating to the one or more lenses to prevent signal loss; and
when the wafer comprises silicon, applying an antireflective coating on a wafer side facing the interposer.
